(19) United States
(12) Patent Application Publication
(10) Pub. No.: US 2010/0283474 A1
(43) Pub. Date: Nov. 11, 2010

(54) TEST CIRCUIT AND OPTICAL PICKUP DEVICE

(75) Inventors: Hideo FUKUDA, Kyoto (JP); Masaki TANIGUCHI, Kyoto (JP); Shinichi MIYAMOTO, Kyoto (JP); Yousuke KUROIWA, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/759,981

(22) Filed: Apr. 14, 2010

(30) Foreign Application Priority Data
May 11, 2009 (JP) 2009-114611
May 14, 2009 (JP) 2009-117119

(51) Int. Cl. G01R 31/308

(52) U.S. Cl. 324/501

(57) ABSTRACT

A test circuit for testing not only characteristics of a current-voltage conversion circuit in which a light-receiving element is used but also characteristics of the light-receiving element includes: a current-mirror circuit 110 including a bipolar transistor Q1 and a bipolar transistor Q2 which are electrically connected to a light-receiving element PD1; a dummy light-receiving element PD_D which is an element identical to the light-receiving element PD1 and is equivalent in characteristics to the light-receiving element PD1; and a test terminal TP which is electrically connected to the bipolar transistor Q1 and the dummy light-receiving element PD_D.

### BACKGROUND OF THE INVENTION

(1) Field of the Invention

The present invention relates to a test circuit and an optical pickup device for testing characteristics of a current-voltage conversion circuit in which a light-receiving element is used.

(2) Description of the Related Art

In an optical disc apparatus which performs processes on an optical disc, a light-receiving amplifier device is used which receives light reflected on the optical disc (the light is hereinafter referred to as reflected light) and converts the reflected light into electric charges. The optical disc may be a compact disc (CD), a digital versatile disc (DVD), or a Blu-ray disc (BD) (“Blu-ray disc” is a registered trademark). The processes which the optical disc apparatus performs on the optical disc include a process of reading data recorded on the optical disc and a process of writing data to the optical disc.

In these years, the scale of semiconductor integrated circuits is increasing with increase in integration degree, functionality, and speed of semiconductor integrated circuits. Because of this, test of functional circuitry in semiconductor integrated circuits is becoming more complex.

In a general process of manufacturing integrated circuits (ICs), operation of internal circuitry and elements inside ICs is checked. For example, operation of a photoelectric conversion element (photodiode) used in a light-receiving amplifier device is preferably checked by irradiating the photoelectric conversion element with direct light. The photoelectric conversion element may be hereinafter referred to as a light-receiving element.

The size of the light-receiving element is, however, as small as of the order of tens of micrometers. This causes a problem that it is very difficult to irradiate the light-receiving element with a predetermined amount of light in practice.

A solution to this problem is disclosed in Patent Reference 1 (Japanese Unexamined Patent Application Publication Number 8-129046). The solution is a test circuit for accurate electrical test of characteristics of a current-voltage conversion circuit in which a light-receiving element is used.

FIG. 15 shows a configuration of a test circuit for a current-voltage conversion circuit in which a light-receiving element is used.

The following is a description of the test circuit disclosed in Patent Reference 1 with reference to FIG. 15.

In FIG. 15, a light-receiving element PD1 is a photodiode which generates a current corresponding to the amount of light with which the light-receiving element PD1 is irradiated. The light-receiving element PD1 has a cathode, which is electrically connected to a node N1, and an anode, which is grounded.

Hereinafter, the status that an object A is electrically connected to an object B is described simply as that an object A is connected to an object B.

A current-voltage conversion circuit 10 outputs a voltage as an output voltage Vout corresponding to the current generated by the light-receiving element PD1.

The current-voltage conversion circuit 10 includes an amplifier unit 11. The amplifier unit 11 is an operational amplifier. A conversion resistor Rg_a is provided between an inverting input terminal and an output terminal of the amplifier unit 11.

A reference voltage Vref is applied to a non-inverting input terminal of the amplifier unit 11.

The current-voltage conversion circuit 10 converts, using the conversion resistor Rg_a, a current generated by irradiating the light-receiving element PD1 with light (the current may be hereinafter referred to as a photocurrent) into a voltage, and then outputs the voltage resulting from the conversion as the output voltage Vout. The level of the output voltage Vout is determined by a resistance value of the conversion resistor Rg_a and the reference voltage Vref.

The test circuit 2000 is a circuit for testing characteristics (operation) of the current-voltage conversion circuit 10.

The test circuit 2000 includes a current-mirror circuit 110, resistors R3 and R4, and a test terminal TP. The current-mirror circuit 110 includes bipolar transistors Q1 and Q2 and resistors R1 and R2.

Each of the bipolar transistors Q1 and Q2 is an NPN transistor. The bipolar transistor Q2 has a collector terminal which is connected to the node N1. The bipolar transistor Q2 has an emitter terminal which is connected to the resistor R2. The bipolar transistor Q2 has a base terminal which is connected to a base terminal of the bipolar transistor Q1.

The bipolar transistor Q1 has a collector terminal which is connected to the resistor R3. The bipolar transistor Q1 has an emitter terminal which is connected to the resistor R1. The resistor R1 has the same resistance value as the resistance value of the resistor R2.

The test terminal TP is connected to the resistor R4 and the resistor R3.

When a test voltage is applied to the test terminal TP, the test voltage is converted into a current Ia which is determined by a base-emitter voltage (Vbe) of the bipolar transistor Q1 and the resistor R3. This means that in the collector terminal of the bipolar transistor Q1 there flows the current Ia.

In this case, the current-mirror circuit 110 including the resistors R1 and R2 which have the same resistance value, passes, to the collector terminal of the bipolar transistor Q2, a current Ib which has the same current value as the current value of the current Ia. In other words, the current Ib flows from the inverting input terminal of the amplifier unit 11 to the collector terminal of the bipolar transistor Q2. That is, the current Ib is drawn from the inverting input terminal of the amplifier unit 11. The current-voltage conversion circuit 10 then outputs a voltage as an output voltage Vout corresponding to the current Ib.

The test circuit described in Patent Reference 1, however, a problem with a line that connects the light-receiving element and the current-voltage conversion circuit, such as a break, cannot be detected.

Patent Reference 2 (Japanese Unexamined Patent Application Publication Number 10-284707) discloses a test circuit with which such a problem with a line that connects a light-receiving element and a current-voltage conversion circuit, such as a break, can be detected.

FIG. 16A shows a configuration of a test circuit described in Patent Reference 2. FIG. 16B shows a cross section of a light-receiving element 901.

The test circuit is described below with reference to FIG. 16A and FIG. 16B.

The light-receiving element 901 is a photodiode which generates a current corresponding to the amount of light with which the light-receiving element 901 is irradiated. The light-receiving element 901 has terminals T1 and T2 at its cathode. The terminal T1 is connected to a current-voltage conversion circuit 902 through a line H1. The terminal T2 is connected to a test circuit 903 with a line H2.

The test circuit 903 is a test circuit which allows detection of a problem with the line H1 which connects the light-receiving element 901 and the current-voltage conversion circuit 902.

The test circuit 903 includes a switching circuit 931, a constant-current circuit 932, and an on/off circuit 933.

The switching circuit 931 is set to either on or off according to external control. When the switching circuit 931 is on, the terminal T2 and the constant-current circuit 932 are electrically connected. When the switching circuit 931 is off, the terminal T2 and the constant-current circuit 932 are electrically disconnected.

The on/off circuit 933 switches the switching circuit 931 between on and off.

In the circuit shown in FIG. 16A, the current flowing between the current-voltage conversion circuit 902 and the test circuit 903 necessarily passes the line H1 which connects the light-receiving element 901 and the current-voltage conversion circuit 902, and then the terminal T2 of the light-receiving element 901.

Thus, the test circuit 903 cannot provide the current-voltage conversion circuit 902 with a current when there is a problem, such as a break, with the line H1 which connects the light-receiving element 901 and the current-voltage conversion circuit 902. The problem, such as a break, with the line H1 which connects the light-receiving element 901 and the current-voltage conversion circuit 902 can be detected by finding no change in output voltage from the output terminal To of the current-voltage conversion circuit 902.

However, there is a problem that neither of the test circuit disclosed in Patent Reference 1 nor the one disclosed in Patent Reference 2 allows test of both characteristics of a current-voltage conversion circuit in which a light-receiving element is used and characteristics of the light-receiving element.

### SUMMARY OF THE INVENTION

The present invention, conceived to address the problem, has an object of providing a test circuit and an optical pickup device each of which allows test not only of characteristics of a current-voltage conversion circuit in which a light-receiving element is used but also of characteristics of the light-receiving element.

In order to achieve the object, a test circuit according to an aspect of the present invention is a circuit for testing characteristics of a current-voltage conversion circuit which outputs a voltage corresponding to a photocurrent generated by a light-receiving element corresponding to an amount of light with which the light-receiving element is irradiated. The test circuit includes: a current-mirror circuit which includes a first bipolar transistor and a second bipolar transistor which is electrically connected to the light-receiving element; a dummy light-receiving element which is identical to the light-receiving element and equivalent in characteristics to the light-receiving element; and a test terminal which is electrically connected to the first bipolar transistor and the dummy light-receiving element.

For example, a current source is connected to the test terminal so that a test current for testing characteristics of the dummy light-receiving element from the dummy light-receiving element to the test terminal. Then, the characteristics of the dummy light-receiving element can be tested by measuring the voltage of the test terminal voltage at this time. It is noted that the dummy light-receiving element is equivalent in characteristics to the light-receiving element.

Thus, characteristics of the light-receiving element are tested in addition to characteristics of the current-voltage conversion circuit in which the light-receiving element is used.

Furthermore, when a voltage for testing the current-voltage conversion circuit is applied to the test terminal, the current-mirror circuit causes, by using the second bipolar transistor, a test current for testing the characteristics of the current-voltage conversion circuit to be generated in the current-voltage conversion circuit. It is preferable that the first bipolar transistor in the current-mirror circuit turns off when the test current for testing the characteristics of the dummy light-receiving element flows from the dummy light-receiving element to the test terminal.

Furthermore, it is preferable that the first bipolar transistor is an NPN transistor, the NPN transistor is formed in a P-type substrate, and the dummy light-receiving element is formed of the P-type substrate and an N-type diffusion region which is a collector region of the NPN transistor.

In other words, the first bipolar transistor and the dummy light-receiving element are formed as a unit. The test circuit is thus reduced in size.

Furthermore, it is preferable that a first light-receiving region of the dummy light-receiving element for receiving light in the first light-receiving region has an area equal to or larger than an area of a second light-receiving region of the light-receiving region for receiving light in the second light-receiving region.

Furthermore, it is preferable that the first light-receiving region of the dummy light-receiving element is covered with a photo-shield film so as not to be irradiated with light.

With this, the dummy light-receiving element receives no light even when light is emitted toward the dummy light-receiving element. Thereby accuracy of the test of characteristics of light-receiving elements is increased.

An optical pickup device according to another aspect of the present invention includes the test circuit.

A test circuit according to another aspect of the present invention is a circuit for testing a current-voltage conversion circuit included in a light-receiving amplifier circuit formed on a substrate. The light-receiving amplifier circuit includes: a light-receiving element which generates a photocurrent corresponding to an amount of light with which the light-receiving element is irradiated; a current-voltage conversion circuit which converts the photocurrent to a voltage; and a first connection line which includes lines provided in wiring layers on the substrate and contacts. The light-receiving element has an output terminal which is electrically connected to an input terminal of the current-voltage conversion circuit via at least the first connection line during test of the current-voltage conversion circuit. The test circuit includes: a test terminal; a first test circuit; and a second test circuit. The first test circuit includes: a current-mirror circuit having an input terminal and an output terminal; and a resistor. The input terminal of the current-mirror circuit is electrically connected to the test terminal via at least the resistor. The output terminal of the current-mirror circuit is electrically connected to the output terminal of the light-receiving element. The second test circuit includes: a dummy light-receiving element which is an element identical to the light-receiving element and equivalent in characteristics to the light-receiving element; and a second connection line which is identical in structure to the first connection line and equivalent in characteristics to the first connection line. The dummy light-receiving element has an output terminal which is electrically connected to the test terminal via at least the second connection line during test of the second connection line.

With this configuration, the output terminal of the dummy light-receiving element is electrically connected to the test terminal via at least the second connection line during test of the second connection line. For example, a current source is connected to the test terminal during test of the second connection line so that a test current for testing characteristics of the dummy light-receiving element from the dummy light-receiving element to the test terminal. Then, the characteristics of the dummy light-receiving element can be tested by measuring the voltage of the test terminal voltage at this time. It is noted that the dummy light-receiving element is equivalent in characteristics to the light-receiving element.

Thus, characteristics of the light-receiving element are tested in addition to characteristics of the current-voltage conversion circuit in which the light-receiving element is used.

Furthermore, the characteristics of the current-voltage conversion circuit can be tested using the first test circuit, and the light-receiving element and the second connection line can be tested using the second test circuit. It is noted a second connection line is equivalent in characteristics to the first connection line. Accordingly, it should be understood that the resistance value of the first connection line is also included in the scope of the first connection line.

Furthermore, the input terminal of the first test circuit and the input terminal of the second test circuit are connected to a common test terminal. Thus, the only one test terminal, which is not involved in practical operation, is sufficient for the test circuits for test at reduced costs for chips.

Furthermore, it is noted that the second test circuit includes a dummy light-receiving element which is equivalent in characteristics to the light-receiving element. Thus, change in resistance due to anomalous wiring in a diffusion process can be detected using the dummy light-receiving element.

Furthermore, it is preferable that when a voltage for testing the current-voltage conversion circuit is applied to the test terminal during the test of the current-voltage conversion circuit, the current-mirror circuit causes a test current for testing characteristics of the current-voltage conversion circuit to be generated in the current-voltage conversion circuit.

This configuration allows test of the current-voltage conversion circuit.

Furthermore, it is preferable that the first test circuit is out of operation while a test current for testing the second connection line and the dummy light-receiving element flows from the dummy light-receiving element to the test terminal.

This configuration allows test of whether or not the resistance value of the first connection line is normal by alternatively testing the second connection line.

Furthermore, it is preferable that a resistance of the resistor is 2 kΩ or higher.

Here is an example of a current-mirror circuit which is formed of a plurality of NPN-type transistors. In the example, the input terminal of the current-mirror circuit is a collector terminal of one of the NPN-type transistors, and the substrate is a P-type substrate. With this configuration, the voltage at the test terminal is lower than zero when the second connection line is tested using the second test circuit. This turns on a parasitic diode formed of a PN junction between the input terminal of the current-mirror circuit included in the first test circuit (the collector terminal of the NPN transistor) and the P-type substrate.

At this time, a current flows from the first test circuit to the test terminal. When the resistance value between the input terminal and the test terminal of the current-mirror circuit is large enough, influence on the second test circuit can be ignored.

Specifically, the resistance value is in the order of several ohms when a normal wiring resistance and a contact resistance are provided, while the resistance value is in the order from several hundreds ohms to two kilo-ohms when there is anomalous diffusion. Accordingly, a problem with the wiring resistance and the contact resistance can be detected when the resistance value of the resistance provided between the input terminal of the current-mirror circuit and the test terminal, which are connected in parallel in the circuit configuration, is 2 kΩ.

Furthermore, it is preferable that the first test circuit further includes an N-channel MOS transistor, the N-channel MOS transistor is provided between the resistor and the input terminal of the current-mirror circuit, the N-channel MOS transistor has a source which is connected to the input terminal of the current-mirror circuit, and the N-channel MOS transistor has a gate and a drain which are connected to one end of the resistor.

With this configuration, switching operation of the N-channel MOS transistor turns off the N-channel MOS transistor while the second test circuit is operating. This prevents a current from flowing from the first test circuit to the second test circuit, thus preventing malfunction of the second test circuit.

Furthermore, it is preferable that the second test circuit further includes a P-channel MOS transistor, the P-channel MOS transistor is provided between the second connection line and the test terminal, the P-channel MOS transistor has a source which is connected to the second connection line, and P-channel MOS transistor has a gate and a drain which are connected to the test terminal.

With this configuration, switching operation of the P-channel MOS transistor turns off the P-channel MOS transistor while the first test circuit is operating. This prevents a current from flowing from the second test circuit to the first test circuit, thus preventing malfunction of the first test circuit.

Furthermore, it is preferable that the light-receiving amplifier circuit further includes a switching element which electrically connects and disconnects the output terminal of the light-receiving element and the input terminal of the current-voltage conversion circuit, and the switching element is connected in series to the first connection line.

With this configuration, operation of the switching element shorts and opens between the light-receiving element and the current-voltage conversion circuit. In addition, when the current-voltage conversion circuit is provided with a plurality of light-receiving elements, switching of the switching element provided to each of the light-receiving elements allows selection of the one to be connected to the current-voltage conversion circuit from the plurality of light-receiving elements.

Furthermore, it is preferable that the dummy light-receiving element is covered with a photo-shield film, and the photo-shield film is a metal film provided in an uppermost layer of the wiring layers.

With this configuration, the dummy light-receiving element receives no light during practical use, and thus preventing influence of malfunction of the second test circuit on the light-receiving amplifier circuit currently in use. In the case where the photo-shield film is a metal film provided uppermost, freedom of wiring layout near the dummy light-receiving element is increased.

Furthermore, the present invention may be implemented as an optical pickup device which includes the test circuit and a light-receiving amplifier circuit to be test. The optical pickup device reads out information from optical discs and writing information to optical discs using laser beams. The optical pickup device includes the test circuit and the light-receiving amplifier circuit to be tested. The light-receiving amplifier circuit receives reflected light from the optical disc using the light-receiving element and outputs an electric signal.

This configuration provides an optical pickup device which has the various features of the test circuit.

According to the present invention, characteristics of the light-receiving element are thus tested in addition to characteristics of the current-voltage conversion circuit in which the light-receiving element is used.

### FURTHER INFORMATION ABOUT TECHNICAL BACKGROUND TO THIS APPLICATION

The disclosure of Japanese Patent Application No. 2009-114611 filed on May 11, 2009 including specification, drawings and claims is incorporated herein by reference in its entirety. Furthermore, the disclosure of Japanese Patent Application No. 2009-117119 filed on May 14, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows a configuration of an optical semiconductor device according to Embodiment 1;

FIG. 2 shows operation of a test circuit operating in a first test mode;

FIG. 3 shows a characteristic line which represents relationship between an output voltage Vout and a test current;

FIG. 4 shows operation of the test circuit operating in a second test mode;

FIG. 5 shows characteristics of a dummy light-receiving element.

FIG. 6 is a cross-section view of a substrate in which a test circuit is formed;

FIG. 7 is a cross-section view of a bipolar transistor and the dummy light-receiving element according to Embodiment 1;

FIG. 8 is a cross-section view of the bipolar transistor and the dummy light-receiving element according to Variation of Embodiment 1;

FIG. 9 is a top view of the bipolar transistor and the dummy light-receiving element according to Variation of Embodiment 1;

FIG. 10 shows a configuration of an optical semiconductor device according to Embodiment 2;

FIG. 11A is a cross-section view of a light-receiving element and a connection line according to Embodiment 2;

FIG. 11B is a cross-section view of a dummy light-receiving element and the connection line according to Embodiment 2;

FIG. 12 is a characteristic chart of a second test circuit according to Embodiment 2;

FIG. 13 shows a configuration of an optical semiconductor device according to Embodiment 2;

FIG. 14 shows an example of a configuration of an optical pickup device;

FIG. 15 shows a configuration of a test circuit for a current-voltage conversion circuit in which a light-receiving element is used;

FIG. 16A shows a configuration of a test circuit described in Patent Reference 2; and

FIG. 16B shows a cross section of a light-receiving element.

### DESCRIPTION OF THE PREFERRED EMBODIMENTS

Embodiments of the present invention are described below with reference to drawings. In the following, like reference numerals refer to like parts. The like parts have an identical name and identical functions. Thus a detailed description thereof is not repeated here.

### Embodiment 1

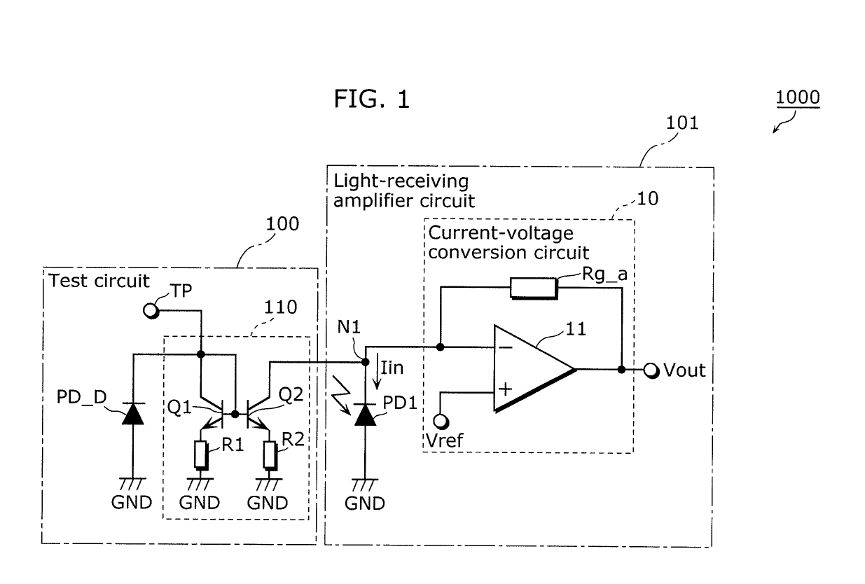

FIG. 1 shows a configuration of an optical semiconductor device 1000 according to Embodiment 1.

Referring to FIG. 1, the optical semiconductor device 1000 includes a light-receiving amplifier circuit 101 and a test circuit 100. The light-receiving amplifier circuit 101 includes a current-voltage conversion circuit 10 and a light-receiving element PD1.

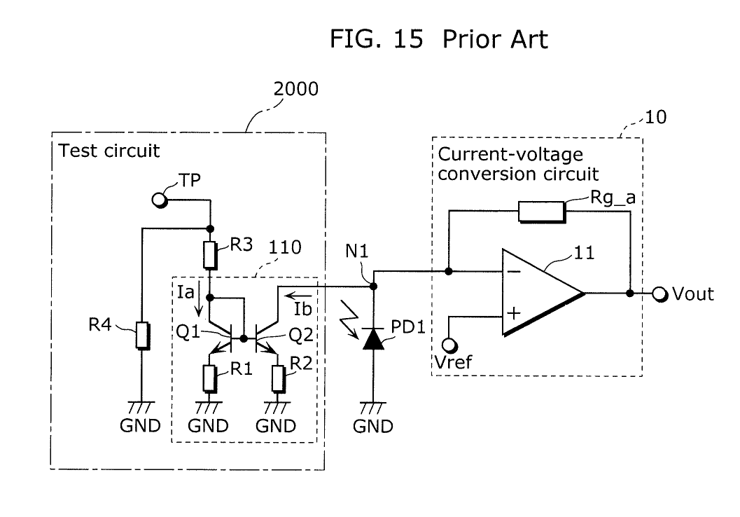

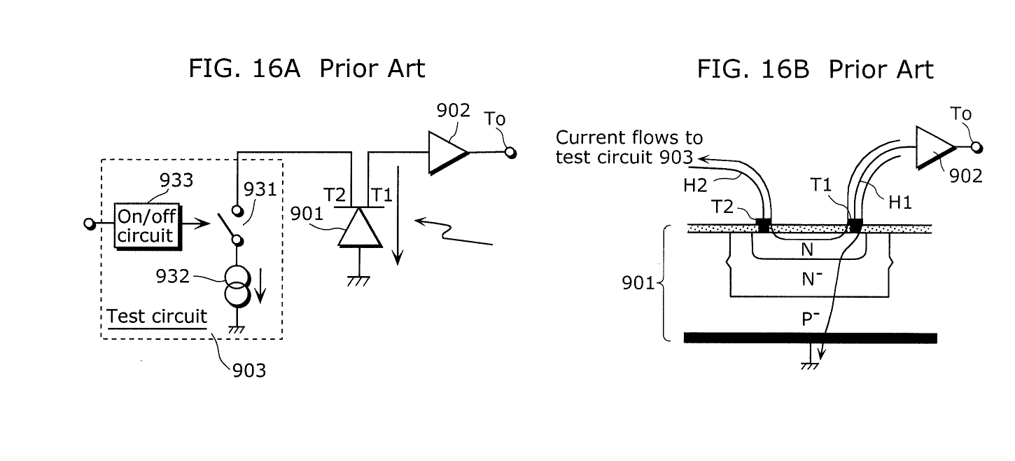

A current-voltage conversion circuit 10 shown in FIG. 1 has a configuration and functions identical to those of the current-voltage conversion circuit 10 shown in FIG. 15, thus a detailed description thereof is not repeated here. The following is a brief description of the current-voltage conversion circuit 10. A conversion resistor Rg_a is provided between an inverting input terminal and an output terminal of the amplifier unit 11 included in the current-voltage conversion circuit 10. A reference voltage Vref is applied to a non-inverting input terminal of the amplifier unit 11.

A light-receiving element PD1 shown in FIG. 1 is identical to the light-receiving element PD1 shown in FIG. 15, thus a detailed description thereof is not repeated here. The following is a brief description of the light-receiving element PD1. The light-receiving element PD1 is a photodiode which generates a current corresponding to the amount of light with which the light-receiving element PD1 is irradiated. The light-receiving element PD1 has a cathode, which is electrically connected to an inverting input terminal of the amplifier unit 11, and an anode, which is grounded.

Hereinafter, the status that an object A is electrically connected to an object B is described simply as that an object A is connected to an object B.

The test circuit 100 differs from the test circuit 2000 shown in FIG. 15 in that the test circuit 100 does not include the resistor R3 or R4 but further includes a dummy light-receiving element PD-D. This is the only differences between the test circuit 100 and the test circuit 2000, thus detailed description of the like components is not repeated here.

The following is a brief description of the test circuit 100. A current-mirror circuit 110 of the test circuit 100 includes bipolar transistors Q1 and Q2 each of which is an NPN transistor. The bipolar transistor Q2 has a collector terminal which is connected to the cathode of the light-receiving element PD1. The collector terminal of the bipolar transistor Q2 is also an output terminal of the current-mirror circuit 110.

The bipolar transistor Q1 has a collector terminal which is connected to a test terminal TP. The collector terminal of the bipolar transistor Q1 is also an input terminal of the current-mirror circuit 110.

A resistor R1 is provided between an emitter terminal of the bipolar transistor Q1 and a GND. A resistor R2 is provided between an emitter terminal of the bipolar transistor Q2 and the GND. The resistor R1 has the same resistance value as the resistance value of the resistor R2, although the resistance value of the resistor R1 may differ from the resistance value of the resistor R2. For example, the resistor R1 and the resistor R2 may be designed to have resistance values in a predetermined ratio, such as 1:2.

The dummy light-receiving element PD_D is a photodiode. The dummy light-receiving element PD_D is identical in electrical characteristics to the light-receiving element PD1. The dummy light-receiving element PD_D and the light-receiving element PD1 are manufactured in the same step of a manufacturing process.

The bipolar transistor Q1 has a collector terminal which is connected to a cathode of the dummy light-receiving element PD_D. An anode of the dummy light-receiving element PD_D is grounded.

The current-mirror circuit 110 may be formed not of the two NPN transistors but of two PNP transistors instead.

The following is a brief description of the test circuit 100. The test circuit 100 operates in three operational modes: a normal operation mode, a first test mode, and a second test mode. The first test mode is a mode for testing characteristics (operation) of the current-voltage conversion circuit 10. The second test mode is a mode for testing (testing) characteristics of the light-receiving element PD1.

When the test circuit 100 operates in the normal operation mode, irradiation of the light-receiving element PD1 with light causes the light-receiving element PD1 to generate a current corresponding to the amount of the light (the current is hereinafter referred to as photocurrent). The photocurrent generated by the light-receiving element PD1 is denoted by I1n. In this case, the photocurrent I1n flows from the inverting input terminal of the amplifier unit 11 to the light-receiving element PD1.

The output voltage Vout of the current-voltage conversion circuit 10 is represented by EQ. 1 below.

Vout=Rga×I1n (EQ. 1),

where Rga denotes a resistance value of the conversion resistor Rg_a.

When the test circuit 100 is operating in the normal operation mode, no voltage is applied to the test terminal TP; thus, no current flows to the collector terminal of the bipolar transistor Q1.

The following is a description of operation of the test circuit 100 while the test circuit 100 is operating in the first test mode.

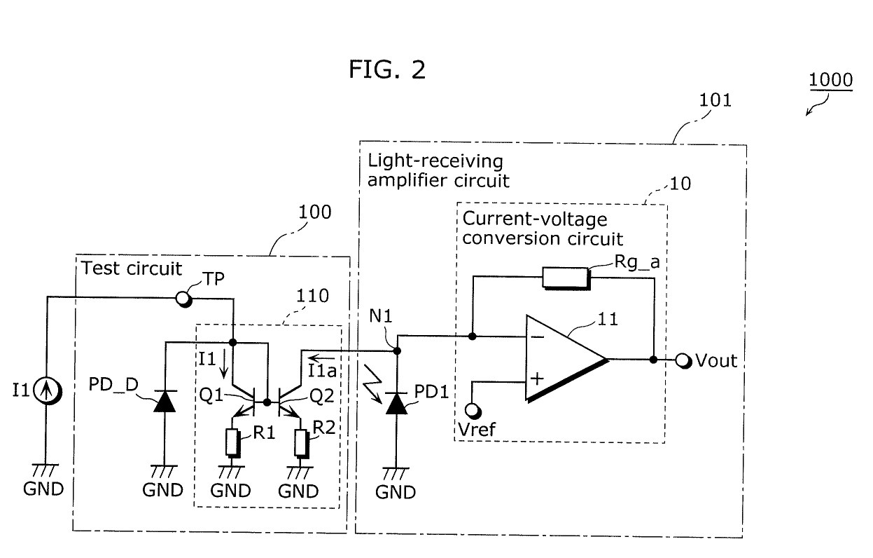

Operation of the test circuit 100 operating in the first test mode is described below with reference to FIG. 2.

In this case, for the purpose of testing characteristics (operation) of the current-voltage conversion circuit 10, a test voltage is externally applied to the test terminal TP so that a test current I1 flows from the test terminal TP to the collector terminal of the bipolar transistor Q1. The test voltage is a voltage for testing the current-voltage conversion circuit 10.

At this time, the current-mirror circuit 110 operates to cause a current I1a to flow to the collector terminal of the bipolar transistor Q2. The current I1a and the test current I1 has the same current value. In other words, the current-mirror circuit 110 causes, by using the bipolar transistor Q2, the test current for testing the characteristics of the current-voltage conversion circuit 10 to be generated in the current-voltage conversion circuit 10. The test current has a current value identical to the current value of the current flowing from the test terminal TP to the bipolar transistor Q1.

The output voltage Vout of the current-voltage conversion circuit 10 is represented by EQ. 2 below.

Vout=Rga×I1a (EQ. 2)

Here, the relationship between the output voltage Vout and the test current I1a is represented by a characteristic line L1 described below.

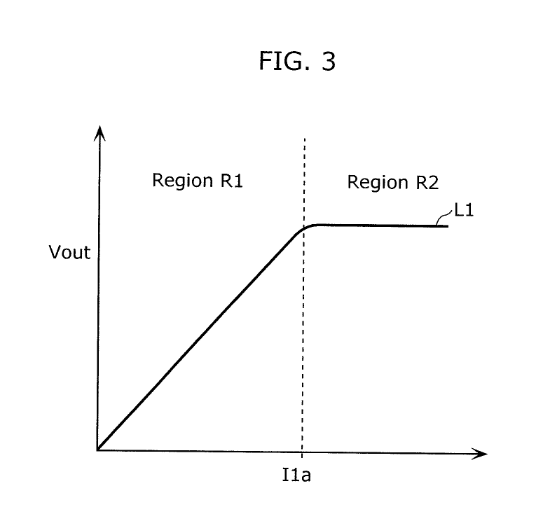

FIG. 3 shows the characteristic line L1 which represents relationship between the output voltage Vout and the test current I1a.

In a region R1, the output voltage Vout increases in proportion to the test current I1a. The slope of the characteristic line L1 in the region R1 is Rga. In a region R2, on the other hand, the output voltage Vout is constant because the amplifier unit 11 operates in a saturation region.

This means that by changing (sweeping) the test current I1 (test current I1a) while the amplifier unit 11 is operating in the saturation region, a test can be performed to find whether or not a gain Rga of the amplifier unit 11 has a predetermined value. Furthermore, this test also serves to determine whether or not obtaining amplitude of a large signal is impossible due to a decrease in the potential of the output voltage Vout in the region R2. In other words, characteristics (operation) of the current-voltage conversion circuit 10 (amplifier unit 11) is thus tested.

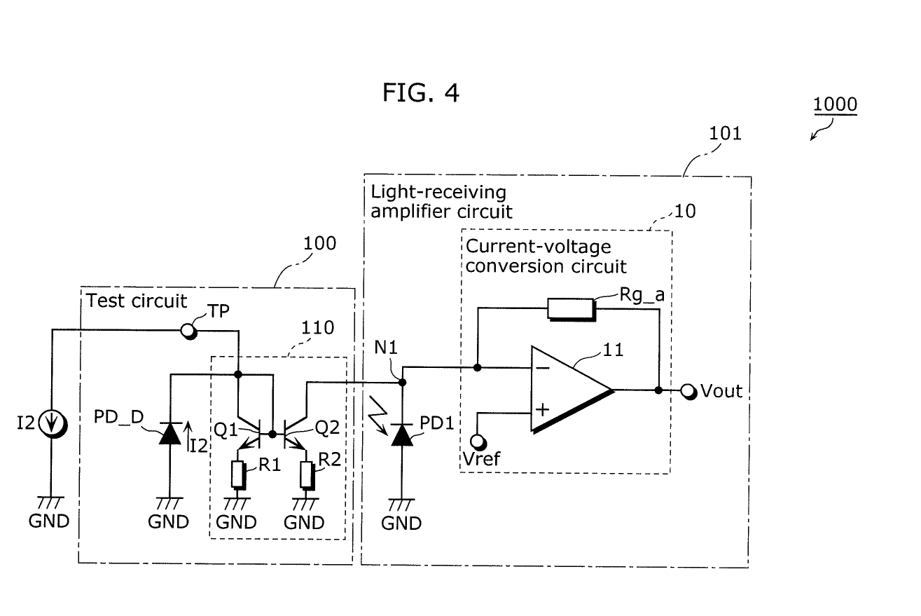

The following is a description of operation of the test circuit 100 while the test circuit 100 is operating in the second test mode. Operation of the test circuit 100 operating in the second test mode is described below with reference to FIG. 4.

In this case, for the purpose of testing characteristics (operation) of the light-receiving element PD1, a current source is externally connected to the test terminal TP so that a test current 12 flows from the dummy light-receiving element PD_D to the test terminal TP. With this configuration, the dummy light-receiving element PD_D functions as a diode, and a test voltage is generated at the test terminal TP (the voltage is hereinafter referred to as a test terminal voltage). The test terminal voltage is lower than 0 V.

Because the voltage at the test terminal TP is lower than 0 V, the bipolar transistor Q1 turns off with no current flowing from the collector terminal to the emitter terminal. The test current 12 then flows from the cathode of the dummy light-receiving element PD_D to the test terminal TP. In other words, the test current 12 flows through the dummy light-receiving element PD_D. The dummy light-receiving element PD_D is a photodiode. The test current 12 thus flows through the dummy light-receiving element PD_D in a forward direction. Characteristics of the dummy light-receiving element PD_D can be then tested by measuring the voltage of the test terminal voltage at this time.

Specifically, the bipolar transistor Q1 of the current-mirror circuit 110 turns off when the test current flows from the dummy light-receiving element PD_D to the test terminal TP.

Alternatively, in order to test characteristics (operation) of the light-receiving element PD1, a test voltage (for example, a negative voltage) may be applied to the test terminal TP to pass a test current from the dummy light-receiving element PD_D to the test terminal TP.

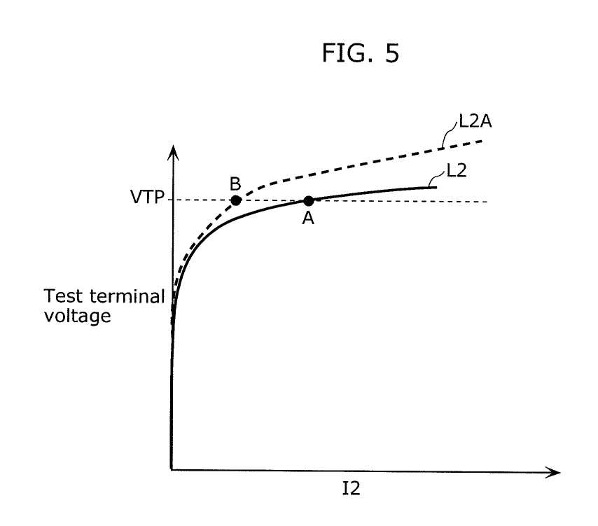

Characteristics of the dummy light-receiving element PD_D is described below with reference to FIG. 5.

FIG. 5 shows the characteristic lines L2 and L2A which represent relationship between the test terminal voltage and the test current 12. Each of the characteristic line L2 and L2A represents a forward characteristic of the dummy light-receiving element PD_D.

The characteristic line L2 shows the relationship when a value of equivalent series resistance component of the dummy light-receiving element PD_D is at a normal level. In other words, the characteristic line L2 is a characteristic line for the dummy light-receiving element PD_D with normal characteristics. The value of the equivalent series resistance component of the dummy light-receiving element PD_D is hereinafter referred to as a series resistance component value.

The series resistance component value is obtained by, for example, calculating a slope of the characteristic line L2 at a point A where the test terminal voltage is VTP.

The characteristic line L2A represents the relationship when the series resistance component value is greater than a normal level.

Again, the series resistance component value is obtained by calculating a slope of the characteristic line L2A at a point B where the test terminal voltage is VTP.

In the case where the test circuit 100 is operating in the second test mode, tested are characteristics of the dummy light-receiving element PD_D. As described above, the dummy light-receiving element PD_D is identical in electrical characteristics to the light-receiving element PD1. Thus, characteristics of the dummy light-receiving element PD_D can be tested by testing not characteristics of the light-receiving element PD1 but characteristics of the dummy light-receiving element instead.

Typically, a surge protection diode is provided between the test terminal TP and the ground terminal in order to protect the test circuit against a surge voltage during the test. However, the dummy light-receiving element PD_D in the test circuit 100 functions also as a surge protection diode. Thus, no surge protection diode is necessary for Embodiment 1, thus preventing increase in chip size of the test circuit 100 by the volume of the surge protection diode.

Furthermore, as described below, an upper portion of the dummy light-receiving element PD_D is covered with a photo-shield film so that the dummy light-receiving element PD_D is not irradiated with light. The photo-shield film may be, for example, a metal film used as a line. By providing the photo-shield film, error due to a current generated by stray light (the current is hereinafter referred to as stray-light current) is prevented even when stray light is emitted toward the dummy light-receiving element PD_D during the test. Thereby, accuracy of the test of characteristics of the dummy light-receiving element PD_D (and thus the light-receiving element PD1) is increased.

The following is a description of reduction in size of circuitry, which is one of principles of the present invention.

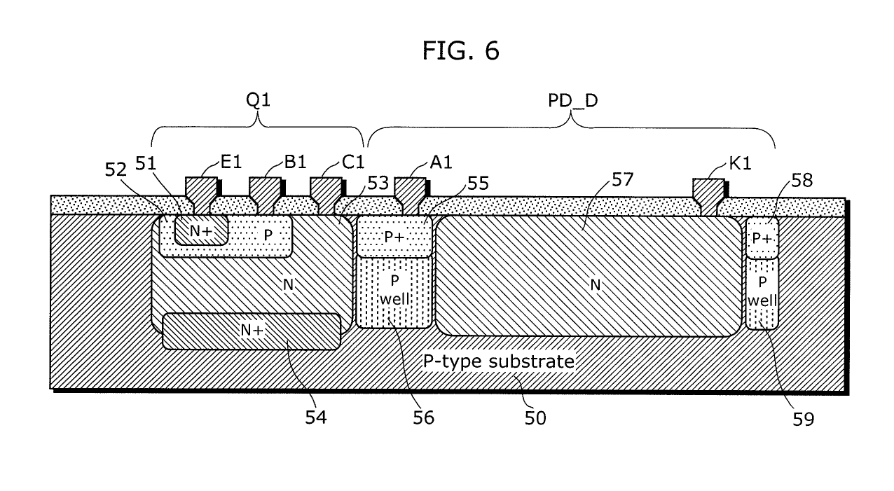

FIG. 6 is a cross-section view of a substrate in which the test circuit 100 is formed.

In FIG. 6, the bipolar transistor Q1 and the dummy light-receiving element PD_D are formed in a p-type substrate 50.

The bipolar transistor Q1 includes an emitter terminal El, a base terminal B1, a collector terminal C1, an emitter region 51, a base region 52, and a collector region 53. The emitter region 51, the base region 52, and the collector region 53 are an N+-type diffusion region, a P-type diffusion region, and an N-type diffusion region, respectively.

Typically, an N+-type diffusion region (hereinafter referred to as an N+-type buried layer) 54 is provided between the collector region 53 and the P-type substrate 50 in order to decrease collector resistance of the bipolar transistor Q1.

A dummy light-receiving element PD_D formed using a conventional technique includes an anode terminal A1, a cathode terminal K1, an anode region 55, a P well 56, a cathode region 57, a P+-type diffusion region 58, and a P well 59. The anode region 55 and the cathode region 57 are a P₊-type diffusion region and an N-type diffusion region, respectively.

Typically, the test circuit 100 shown in FIG. 1 formed in a substrate using a conventional technique includes the bipolar transistor Q1 and the dummy light-receiving element PD_D arranged side by side in the P-type substrate 50 as shown in FIG. 6. In this case, there is a problem that the chip size of the test circuit is large.

Focusing on the layer structure of the bipolar transistor Q1, which is an NPN-type transistor, the inventor of the present invention has conceived an idea to use a parasitic diode formed between the collector region 53 of the bipolar transistor Q1 and the P-type substrate 50 as a dummy light-receiving element.

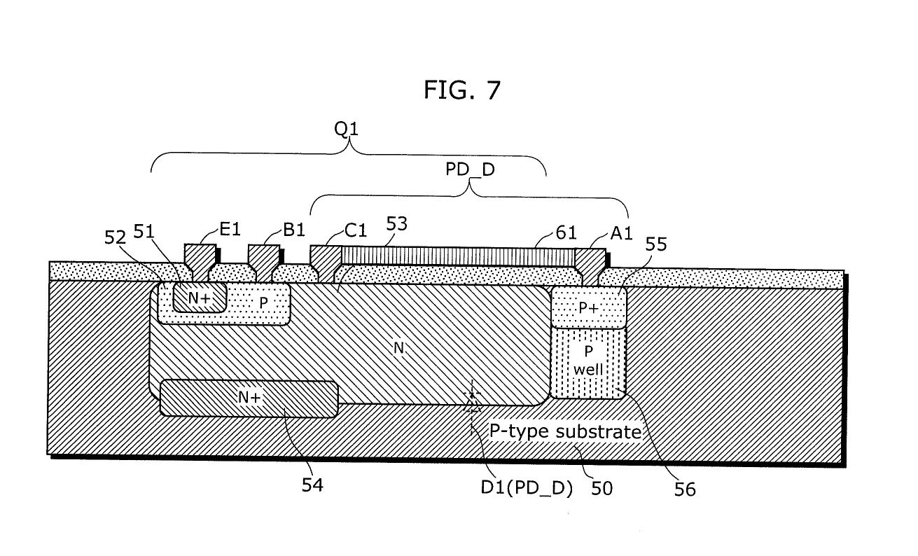

FIG. 7 is a cross-section view of the bipolar transistor Q1 and the dummy light-receiving element PD_D according to Embodiment 1.

In FIG. 7, like reference numerals refer to like elements in FIG. 6, thus a detailed description thereof is not repeated here. The collector region 53 of the bipolar transistor Q1 shown in FIG. 7 has the same impurity concentration as that of the cathode region 57 of the dummy light-receiving element PD_D shown in FIG. 6.

This makes the structure of the collector region 53 in a parasitic diode D1 formed between the collector region 53 of the bipolar transistor Q1 and the P-type substrate 50 equivalent to the structure of the cathode region 57 of the dummy light-receiving element PD_D shown in FIG. 6.

Thereby, the parasitic diode D1 can be used as the dummy light-receiving element PD_D. In this case, the parasitic diode D1 which functions as the dummy light-receiving element PD_D is formed of the N-type diffusion region, which is the collector region 53 of the bipolar transistor Q1, and the P-type substrate 50. The collector region 53 of the bipolar transistor Q1 is used also as a cathode region of the parasitic diode D1 (that is, the dummy light-receiving element PD_D). In other words, according to Embodiment 1, the bipolar transistor Q1 and the dummy light-receiving element PD_D are formed integrally.

In this case, the collector terminal C1 is used also as a cathode terminal of the dummy light-receiving element PD_D.

The parasitic diode D1, which is the dummy light-receiving element PD_D, has a region for receiving light (the region is hereinafter referred to as a light-receiving region). Above the light-receiving region, a photo-shield film 61 is formed so that the light-receiving region is not irradiated with light. In other words, the light-receiving region is covered with the photo-shield film 61. The photo-shield film 61 may be, for example, a metal film used as a line.

Even when stray light is emitted toward the dummy light-receiving element PD_D during the test, this structure prevents error due to a current generated by the stray light (the current is hereinafter referred to as stray-light current). Thereby, accuracy of the test of characteristics of the dummy light-receiving element PD_D (and thus the light-receiving element PD1) is increased.

As describe above, the test circuit 100 according to Embodiment 1 allows test of a characteristic (series resistance component value) of the light-receiving element PD1 (the dummy light-receiving element PD_D) as well as the test of characteristics of the current-voltage conversion circuit 10 in which the light-receiving element PD1 is used.

A large series resistance component value indicates that there is a large resistance between the amplifier unit 11 and the light-receiving element PD1. Such a large resistance deteriorates high-frequency characteristics of the amplifier unit 11. In these years, there is a demand for high-speed record and reproduction of optical discs as typified by Blu-ray discs (BD), and thus there is a demand for high-frequency characteristics of light-receiving amplifier circuits

By using the test circuit 100 according to Embodiment 1, the amplifier unit 11 (an IC) having insufficient high-frequency characteristics is easily detected through test of characteristics of the light-receiving element PD1 (that is, the dummy light-receiving element PD_D).

Furthermore, by forming the bipolar transistor Q1 and the dummy light-receiving element PD_D integrally, the chip area of the test circuit 100 which includes the bipolar transistor Q1 and the dummy light-receiving element PD_D can be reduced. Consequently, the size of the light-receiving amplifier circuit 101 including the test circuit 100 is reduced, and thus the cost of the light-receiving amplifier circuit 101 is lowered.

### Variation of Embodiment 1

According to Variation of Embodiment 1, the size of the test circuit 100 is further reduced than according to Embodiment 1.

Furthermore, difference between the dummy light-receiving element PD_D and the light-receiving element PD1 in characteristics is reduced by making the size of the dummy light-receiving element PD_D equivalent to or larger than the size of the light-receiving element PD1.

In FIG. 7, as described above, an N+-type diffusion region (hereinafter referred to as an N+-type buried layer) 54 is typically provided between the collector region 53 and the P-type substrate 50 in order to decrease collector resistance of the bipolar transistor Q1. Thus, in Embodiment 1, the structure of the parasitic diode D1 which functions as the dummy light-receiving element PD_D shown in FIG. 7 differs from the structure of the dummy light-receiving element PD_D shown in FIG. 6. Because of the difference, the portion where the N+-type diffusion region 54 is present cannot be used as a dummy light-receiving element.

However, an object of the present invention is testing a characteristic (series resistance component value) of the light-receiving element PD1 (dummy light-receiving element PD_D). For this object, there is no problem with the test circuit even when the collector resistance of the bipolar transistor Q1 is high. Thus, according to Variation of Embodiment 1, the N+-type diffusion region 54 is not included in the structure.

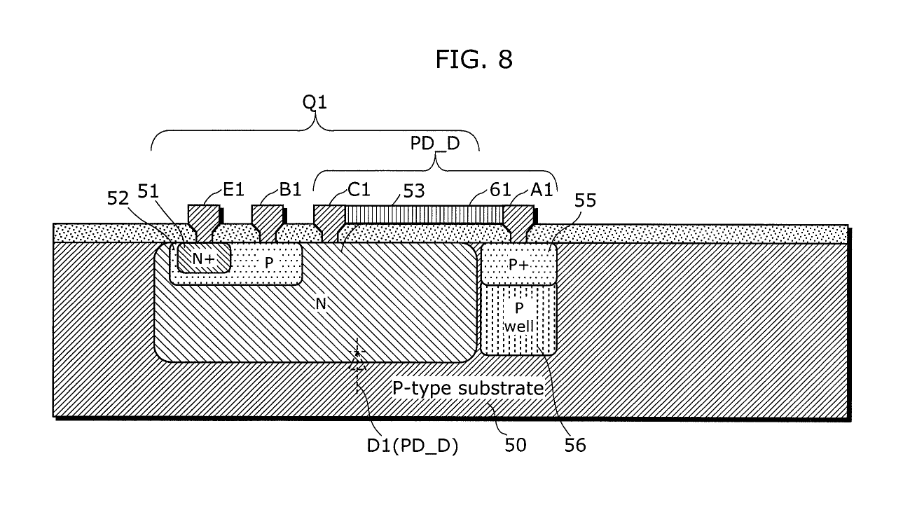

FIG. 8 is a cross-section view of the bipolar transistor Q1 and the dummy light-receiving element PD_D according to Variation of Embodiment 1.

In FIG. 8, like reference numerals refer to like elements in FIG. 7, thus a detailed description thereof is not repeated here.

As shown in FIG. 8, the N+-type diffusion region 54 is not provided between the collector region 53 and the P-type substrate 50. This structure reduces parasitic capacitance between the anode and the cathode of the dummy light-receiving element PD_D.

The parasitic diode D1, which is the dummy light-receiving element PD_D, has a region for receiving light (the region is hereinafter referred to as a light-receiving region). Above the light-receiving region, a photo-shield film 61 is formed so that the light-receiving region is not irradiated with light. In other words, the light-receiving region is covered with the photo-shield film 61.

Furthermore, the bipolar transistor Q1 and the dummy light-receiving element PD_D share a larger area in the structure of the bipolar transistor Q1 and the dummy light-receiving element PD_D as shown in FIG. 8. Thus, according to Variation of Embodiment 1, the size of the test circuit 100 is further reduced than according to Embodiment 1.

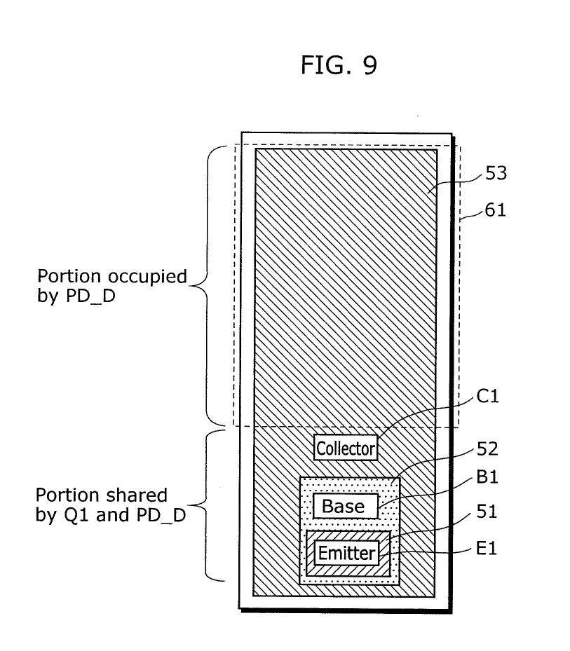

As a result, even when the size of the dummy light-receiving element PD_D (an area of a first light-receiving region described below) is equivalent to or larger than the size of the light-receiving element PD1 (an area of a second light-receiving region describe below), the size of the test circuit 100 according to Variation of Embodiment 1 can be reduced, allowing test with high accuracy. FIG. 9 is a top view of the bipolar transistor Q1 and the dummy light-receiving element PD_D according to Variation of Embodiment 1.

In FIG. 9, like reference numerals refer to like elements in FIG. 8, thus a detailed description thereof is not repeated here.

According to Variation of Embodiment 1, as shown in FIG. 9, the area of the collector region 53 is so large that a region of the dummy light-receiving element PD_D for receiving light (the region is hereinafter referred to as a first light-receiving region) has an area equal to or larger than an area of a region of the light-receiving element PD1 for receiving light (the region is hereinafter referred to as a second light-receiving region).

Referring to FIG. 9, “Portion occupied by PD_D” is a portion where only the dummy light-receiving element PD_D is formed. In the collector region 53, the photo-shield film 61 is formed above the “Portion occupied by PD_D”.

“Portion shared by Q1 and PD_D” is a portion where the bipolar transistor Q1 and part of the dummy light-receiving element PD_D are formed.

Thus, the chip area of the test circuit 100 can be saved by the area of the “Portion shared by Q1 and PD_D”.

The bipolar transistor Q1 and the dummy light-receiving element PD_D are typically formed in the same diffusion process so that the collector region 53 of the bipolar transistor Q1 has the same impurity concentration as that of the cathode region 57 of the dummy light-receiving element PD_D shown in FIG. 6.

The structure according to the present invention is not limited to the one describe above. The dummy light-receiving element PD_D (that is, the parasitic diode D1) and the light-receiving element may be arranged side by side with the light-receiving element PD1. The dummy light-receiving element PD_D (that is, the parasitic diode D1) may be equivalent in size to the light-receiving element PD1. It should be understood that such a structure reduce difference of the dummy light-receiving element PD_D (that is, the parasitic diode D1) and the light-receiving element PD1 in performance.

Furthermore, according to Variation of Embodiment 1, the collector region 53 of the bipolar transistor Q1 has a region to receive light (the region is hereinafter referred to as a light-receiving region). Above the light-receiving region, a photo-shield film 61 is formed so that the light-receiving region is not irradiated with light. In other words, the light-receiving region is covered with the photo-shield film 61. The photo-shield film 61 may be, for example, a metal film used as a line.

Even when stray light is emitted toward the dummy light-receiving element PD_D during the test, this structure prevents error due to a current generated by the stray light (the current is hereinafter referred to as stray-light current). Thereby, accuracy of the test of characteristics of the dummy light-receiving element PD_D (and thus the light-receiving element PD1) is increased.

### Embodiment 2

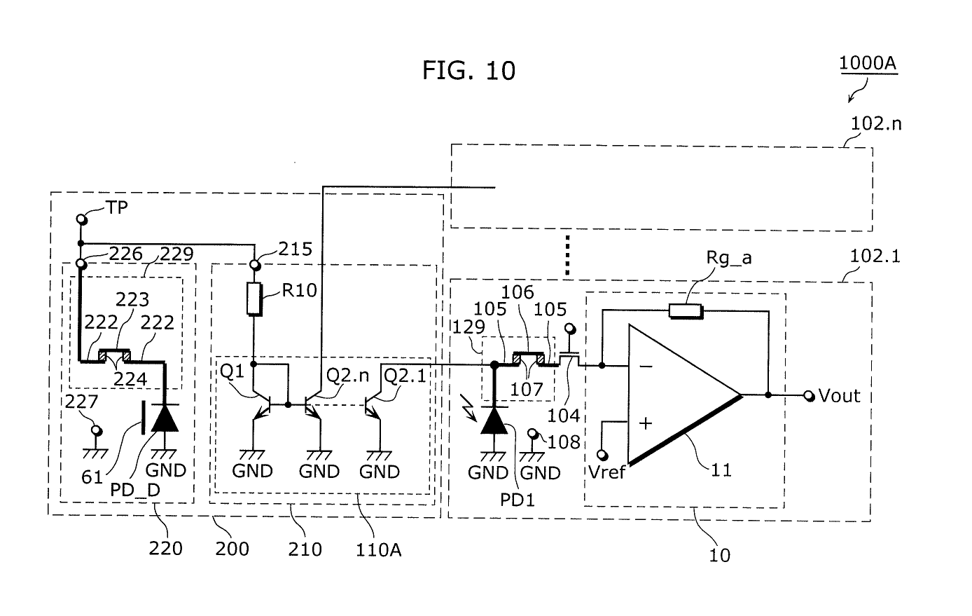

FIG. 10 shows a configuration of an optical semiconductor device 1000A according to Embodiment 2.

The optical semiconductor device 1000A includes light-receiving amplifier circuits 102.1 to 102.n (n is two or an integer greater than two) and a test circuit 200. The light-receiving amplifier circuits 102.1 to 102.n have identical configurations. Each of the light-receiving amplifier circuits 102.1 to 102.n may be hereinafter referred to as a light-receiving amplifier circuit 102.

The light-receiving amplifier circuit 102.1 includes a current-voltage conversion circuit 10, a light-receiving element PD1, and a switching element 104. The current-voltage conversion circuit 10 shown in FIG. 10 has the same configuration and functions as those of the current-voltage conversion circuit 10 shown in FIG. 1, thus a detailed description thereof is not repeated here.

The light-receiving amplifier circuit 102.n has a configuration identical to that of the light-receiving amplifier circuit 102.1.

The switching element 104 is connected in series to a connection line 129. The switching element 104 may be, for example, an N-channel MOS transistor. The switching element 104 is normally in off state and switches to on state according to external control.

The switching element 104 in on state electrically connects an output terminal of the light-receiving element PD1 and an input terminal of the current-voltage conversion circuit 10. The switching element 104 in off state electrically disconnects the output terminal of the light-receiving element PD1 and the input terminal of the current-voltage conversion circuit 10.

The light-receiving element PD1 has a cathode which is connected to the switching element 104 with the connection line 129. The cathode of the light-receiving element PD1 may be hereinafter referred to as an output terminal of the light-receiving element PD1.

The switching element 104 is connected to an inverting input terminal of an amplifier unit 11. Consequently, the cathode of the light-receiving element PD1, which is of an anode-common type, is connected to the inverting input terminal of the amplifier unit 11 via the connection line 129 and the switching element 104.

The inverting input terminal of the switching element 11 may be hereinafter referred to as an input terminal of the amplifier unit 11. In other words, the input terminal of the current-voltage conversion circuit 10 is the input terminal (inverting input terminal) of the amplifier unit 11. Specifically, the output terminal of the light-receiving element PD1 is electrically connected to the input terminal of the current-voltage conversion circuit at least via the connection line 129.

The connection line 129 includes first-layer aluminum lines 105, contacts 107, and a second-layer aluminum line 106. The contacts 107 connect the first-layer aluminum lines 105 and the second-layer aluminum line 106.

The test circuit 200 includes a first test circuit 210 and a second test circuit 220. The first test circuit 210 is connected to a first test-signal input unit 215. The second test circuit 220 is connected to a second test-signal input unit 226. Both of the first test-signal input unit 215 and the second test-signal input unit 226 are connected to a test terminal TP.

The first test circuit 210 and n light-receiving amplifier circuits 102 are formed on one semiconductor substrate. The first test circuit 210 includes a current-mirror circuit 110A and a resistor R10. The current-mirror circuit 110A includes a bipolar transistor Q1 and bipolar transistors Q2.1 to Q2.n. Each of the bipolar transistors Q2.1 to Q2.n is identical to the bipolar transistor Q2 shown in FIG. 1.

The collector terminal of the bipolar transistor Q1 is also an input terminal of the current-mirror circuit 110A. A collector terminal of each of the bipolar transistors Q2.1 to Q2.n is also an output terminal of the current-mirror circuit 110A. Consequently, the current-mirror circuit 110A has n output terminals.

The bipolar transistor Q1 has a base terminal which is connected to a base terminal of each of the bipolar transistors Q2.1 to Q2.n. The bipolar transistors Q2.1 to Q2.n each have a collector terminal which is connected to light-receiving amplifier circuits 102.1 to 102.n, respectively.

More specifically, the collector terminal of the bipolar transistor Q2.1 is connected to the inverting input terminal of the amplifier unit 11 of the light-receiving amplifier circuit 102.1 via the connection line 129 and the switching element 104. Similarly, the collector terminal of the bipolar transistor Q2.n is connected to the inverting input terminal of the amplifier unit 11 of the light-receiving amplifier circuit 102.n via the connection line 129 and the switching element 104.

The bipolar transistor Q1 has a collector terminal which is connected to a first test-signal input unit 215 via the resistor R10. The first test-signal input unit 215 is connected to the test terminal TP. Consequently, the input terminal of the current-mirror circuit 110A is electrically connected to the test terminal TP via the resistor R10.

In the second test circuit 220, the cathode of the dummy light-receiving element PD_D, which is of an anode-common type, is connected to the second test-signal input unit 226 via the connection line 229. The cathode of the dummy light-receiving element PD_D may be hereinafter referred to as an output terminal of the dummy light-receiving element PD_D.

The connection line 229 has a structure and a resistance identical to those of the connection line 129. In other words, the connection line 229 has electrical characteristics identical to those of the connection line 129. Specifically, the connection line 229 includes first-layer aluminum lines 222, contacts 224, and a second-layer aluminum line 223. The contacts 224 connect the first-layer aluminum lines 222 and the second-layer aluminum line 223.

The first-layer aluminum lines 222, the contacts 224, and the second-layer aluminum line 223 are made of materials identical to materials of the first-layer aluminum lines 105, the contacts 107, and the second-layer aluminum line 106, respectively.

Above the dummy light-receiving element PD_D, there is provided a photo-shield film 61 so that the dummy light-receiving element PD_D receives no light.

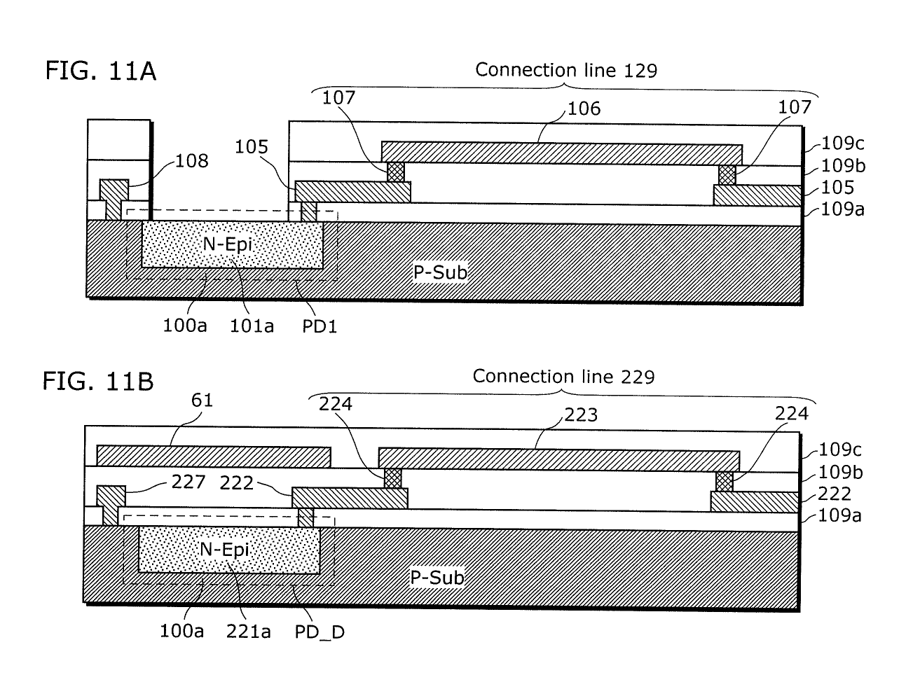

FIG. 11A is a cross-section view of the light-receiving element PD1 and the connection line 129 according to Embodiment 2. FIG. 11B is a cross-section view of the dummy light-receiving element PD_D and the connection line 229 according to Embodiment 2.

FIG. 11A shows the light-receiving element PD1, the first-layer aluminum lines 105, the second-layer aluminum line 106, the contacts 107, and protective films 109a, 109b, and 109c which are included in the light-receiving amplifier circuit 102. The first-layer aluminum lines 105 and the second-layer aluminum line 106 are provided in wiring layers above a P-type semiconductor substrate 100a.

FIG. 11B shows the dummy light-receiving element PD_D, the first-layer aluminum lines 222, the second-layer aluminum line 223, the contacts 224, and protective films 109a, 109b, and 109c which are included in the second test circuit 220. The first-layer aluminum lines 222 and the second-layer aluminum line 223 are provided in the wiring layers above the P-type semiconductor substrate 100a.

As described above, the photo-shield film 61 is provided above the dummy light-receiving element PD_D. The photo-shield film 61 is a metal film provided in the uppermost layer of the wiring layers above the P-type semiconductor substrate 100a. The metal film may be, for example, an aluminum line.

The light-receiving element PD1 includes the P-type semiconductor substrate 100a and an N-type semiconductor layer 101a formed in the P-type semiconductor substrate 100a. The dummy light-receiving element PD_D includes the P-type semiconductor substrate 100a and an N-type semiconductor layer 221a formed in the P-type semiconductor substrate 100a.

The anode terminals 108 and 227 apply GND voltage to the P-type semiconductor substrate 100a. The GND voltage is 0 V.

In the second test circuit 220, an anode of the dummy light-receiving element is connected to an GND as with an anode of the light-receiving element PD1 of the light-receiving amplifier circuit 102 as shown in FIG. 11B. A cathode of the dummy light-receiving element PD_D is connected to the second test-signal input unit 226 via the connection line 229, which has a structure identical to that of the connection line 129. The second test-signal input unit 226 is connected to the test terminal TP. Consequently, the output terminal of the dummy light-receiving element PD_D is electrically connected to the test terminal TP at least via the connection line 229.

When the current-voltage conversion circuit 10 is tested using the first test circuit 210, a test voltage is applied to the test terminal

TP while the switching element 104 is in on state. The test voltage is a voltage for testing the current-voltage conversion circuit 10. The test voltage is higher than 0 V, and high enough to turn on the bipolar transistor Q1, for example, 0.7 V or higher.

In other words, the output terminal of the light-receiving element PD1 is electrically connected to the input terminal of the current-voltage conversion circuit 10 via the connection line 129 and the switching element 104 during the test of the current-voltage conversion circuit 10.

The bipolar transistor Q1 turns on when the test voltage is applied to the test terminal TP.

The applied test voltage is converted into a test current according to the resistor R10 and a base-emitter voltage (hereinafter referred to as Vbe) of the bipolar transistor Q1. At this time, a current equal to the test current is generated at the output terminal of the current-mirror circuit 110A (the current is hereinafter referred to as a mirror current).

In other words, when the test voltage is applied to the test terminal TP during the test of the current-voltage conversion circuit 10, the current-mirror circuit 110A causes the test current for testing the characteristics of the current-voltage conversion circuit 10 to be generated in the current-voltage conversion circuit 10.

The mirror current is converted into an output voltage Vout of the light-receiving amplifier circuit 102 through passing through a conversion resistor Rg_a.

At this time, the dummy light-receiving element PD_D in the second test circuit 220 is reverse-biased. Thus, no current flows through the second test circuit 220. Even when the second test circuit 220 receives light, no photocurrent flows through the dummy light-receiving element PD_D because the light is blocked by the photo-shield film 61 of an aluminum line which is provided in the uppermost layer above the dummy light-receiving element PD_D.

When the connection line 229 is tested using the second test circuit 220, a current source (hereinafter referred to as a test current source) which passes a test current from the dummy light-receiving element PD_D to the test terminal TP is connected to the test terminal TP. The test current is a current for testing the connection line 229 and the dummy light-receiving element PD_D.

With this configuration, a predetermined test current is drawn from the test terminal TP. Thus, the dummy light-receiving element PD_D functions as a diode, and a test voltage is generated at the test terminal TP (the voltage is hereinafter referred to as a test terminal voltage).

The generated test terminal voltage is lower than 0 V. The generated test terminal voltage is a total of a forward voltage across the dummy light-receiving element PD_D and a drop in voltage due to connection line resistance. The connection line resistance is a resistance of the connection line 229. In other words, the connection line resistance is resistance of the connection line 229 in which the first-layer aluminum lines 222, the second-layer aluminum line 223, and the contacts 224 are connected to each other.

Alternatively, in order to test the connection line 229, a test voltage (for example, a negative voltage) may be applied to the test terminal TP to cause a test current to flow from the dummy light-receiving element PD_D to the test terminal TP.

In this case, as the voltage at the test terminal TP is lower than 0 V, the bipolar transistor Q1, which is at an input side of the current-mirror circuit 110A, turns off, and the first test circuit 210 is out of operation. On the other hand, a parasitic diode which is formed of a PN junction between the collector terminal and the semiconductor substrate turns on due to the structure of the bipolar transistor Q1. Thus, if the resistance of the resistor R10 is low, a current flows from the collector terminal of the bipolar transistor Q1 to the test terminal TP via the resistor R10.

In order to prevent this, the resistor R10 has a sufficiently higher resistance than the connection line resistance. For example, the resistance of the resistor R10 is 2 kΩ or higher. This significantly reduces influence of the current from the first test circuit 210; thus allowing accurate test of the connection line resistance, that is, the connection line 229.

As described above, the connection line 229 has electrical characteristics identical to those of the connection line 129. Thus, the connection line 129 is tested by testing the connection line 229.

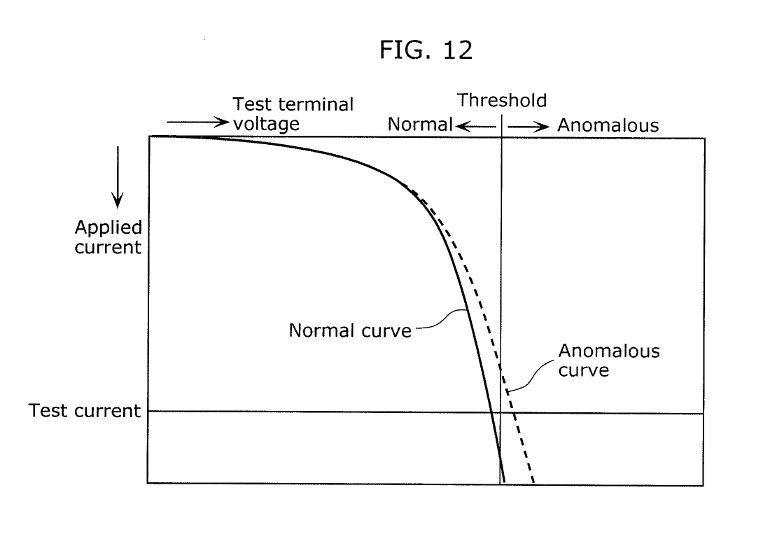

In the case where the first-layer aluminum lines 222, the second-layer aluminum line 223, and the contacts 224 included in the connection line 229 are normally formed, a normal curve represented by a solid line shown in FIG. 12 is observed. In this case, the connection line resistance is, for example, 1 Ω.

On the other hand, in the case where the first-layer aluminum lines 222, the second-layer aluminum line 223, and the contacts 224 are connected to each other so that a resistance larger than a predetermined resistance is produced for a reason such as anomalous diffusion, an anomalous curve shown in FIG. 12 is observed. In this case, the connection line resistance is, for example, 1 kΩ.

The normal curve and the anomalous curve are distinguished by, for example, comparing, with a threshold, test terminal voltages which appears at the test terminal TP when the test current source is connected to the test terminal TP in order to pass a predetermined test current. Furthermore, as with Embodiment 1, characteristics of the dummy light-receiving element PD_D (and thus the light-receiving element PD1) are also tested by measuring a test terminal voltage when the test current source is connected to the test terminal TP.

In the case where an anomalous curve is observed, it is presumed that there is a similar problem with all of the first-layer aluminum lines 105, the second-layer aluminum line 106, and the contacts 107 of the light-receiving amplifier circuit 102 which is formed in the same chip as the second test circuit 220. This is how a problem with the connection line 129 is presumed through an alternative test using the connection line 229.

In other words, characteristics of the dummy light-receiving element PD_D (and thus the light-receiving element PD1) and the connection line 129 are tested by measuring the test terminal voltage of the test terminal TP to which the test current source is connected.

On the other hand, in the case where the light-receiving amplifier circuit 102 is in normal operation, that is, where a photocurrent is converted into a voltage and outputted from the light-receiving amplifier circuit 102, the test terminal TP is open. Thus, neither the current-mirror circuit 110A in the first test circuit 210 nor the dummy light-receiving element PD_D used in the second test circuit 220 receives the test current.

All the current flowing through the conversion resistor Rg_a connected between the inverting input terminal and the output terminal of the amplifier unit 11 of the light-receiving amplifier circuit 102 is the current from the light-receiving element PD1. As a result, the light-receiving amplifier circuit 102 operates normally with no influence of the test circuit 200.

The test circuit 200 according to Embodiment 2 allows tests of the current-voltage conversion circuit 10, the connection line 129, and the dummy light-receiving element PD_D (and thus the light-receiving element) by using the one test terminal TP. Thus, a test circuit is provided which allows detection of a problem with resistance of the connection line 129 connected to the light-receiving element PD1 through simple test.

Furthermore, use of the test circuit 200 according to Embodiment 2 allows test of a device provided with a plurality of light-receiving amplifier circuits (the device is hereinafter referred to as a multifunctional apparatus). In other words, by using the test circuit 200, the multifunctional apparatus can be tested using the one test terminal TP without any other test terminals.

The multifunctional apparatus may be, for example, an apparatus including a plurality of light-receiving amplifier circuits which performs recording and playing of optical discs and switches between a plurality types of optical discs. The plurality types of optical discs include a BD, a DVD, and a CD.

For an optical pickup device, a two-wavelength laser or a three wavelength laser is necessary to support such plurality types of optical discs. Thus, light-receiving elements which support respective types of the optical discs need to be provided on the same semiconductor substrate.

In this case, a plurality of light-receiving elements (not shown) is provided for each of the light-receiving amplifier circuits 102. One switching element is provided for each of the light-receiving elements. One end of each of the switching element is connected to the inverting input terminal of the amplifier unit 11. With this configuration, desired one of the light-receiving elements can be selected by turning on the switching element which is connected to the light-receiving element to be used and turning off the switching element which is connected to the light-receiving element not to be used, so that currents are converted into voltages using the same current-voltage conversion circuit 10.

### Variation of Embodiment 2

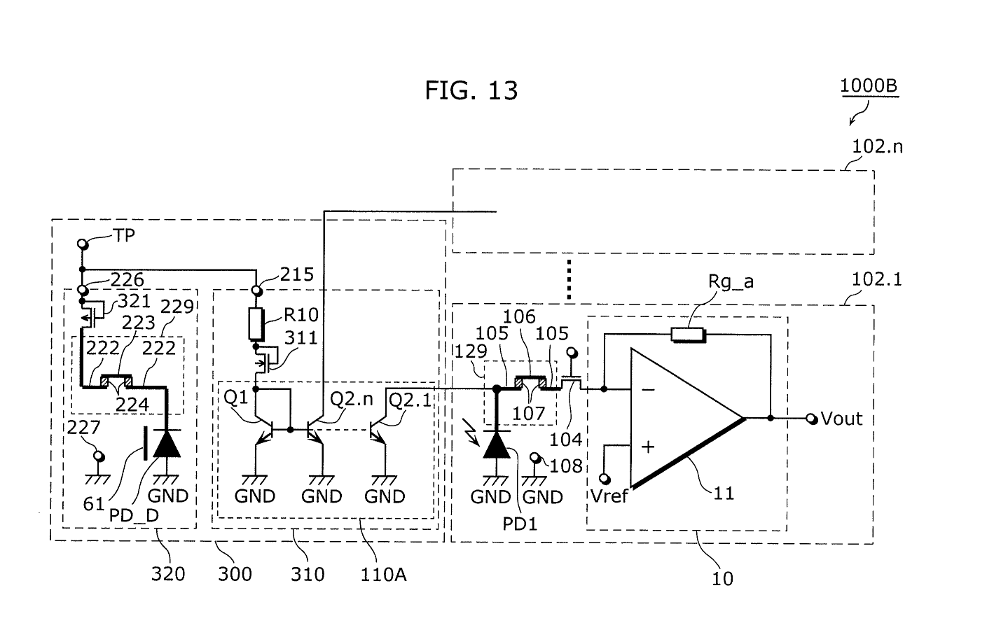

FIG. 13 shows a configuration of an optical semiconductor device 1000B according to Variation of Embodiment 2.

As shown in FIG. 13, the optical semiconductor device 1000B differs from the optical semiconductor device 1000A shown in FIG. 10 in that the optical semiconductor device 1000B includes a test circuit 300 in place of the test circuit 200. This is the only the difference between the optical semiconductor device 1000B and the optical semiconductor device 1000A in configurations, thus detailed description thereof is not repeated here.

The test circuit 300 includes a first test circuit 310 and a second test circuit 320.

The first test circuit 310 differs from the first test circuit 210 shown in FIG. 10 in that the first test circuit 310 further includes an N-channel MOS transistor 311. This is the only difference between the first test circuit 310 and the first test circuit 210 in configurations, thus detailed description thereof is not repeated here.

The N-channel MOS transistor 311 is provided between the resistor R10 and an input terminal of the current-mirror circuit 110A. The second test circuit 320 differs from the second test circuit 220 in that the second test circuit 320 further includes a P-channel MOS transistor 321. This is the only difference between the second test circuit 320 and the second test circuit 220 in configurations, thus detailed description thereof is not repeated here.

The P-channel MOS transistor 321 is provided between the second test-signal input unit 226 and the connection line 229. In other words, the P-channel MOS transistor 321 is provided between the connection line 229 and the test terminal TP.

The N-channel MOS transistor 311 has a source which is connected to the input terminal of the current-mirror circuit 110A of the first test circuit 310. The N-channel MOS transistor 311 has a gate and a drain which are connected to one end of the resistor R10.

The P-channel MOS transistor 321 has a source which is connected to the first-layer aluminum lines 222 on the dummy light-receiving element PD_D of the second test circuit 320. In other words, the source of the P-channel MOS transistor 321 is connected to the connection line 229. The P-channel MOS transistor 321 has a gate and a drain which are connected to the test terminal TP.

As with Embodiment 2, when the current-voltage conversion circuit 10 is tested using the first test circuit 310, a test voltage is applied to the test terminal TP while the switching element 104 is in on state. The test voltage is higher than 0 V. The test voltage is a total of a voltage at which the bipolar transistor Q1 is operating (for example, 0.7 V) and a voltage at which the N-channel MOS transistor 311 is operating (for example, 0.7 V). In this case, the bipolar transistor Q1 and the N-channel MOS transistor 311 turn on.

In other words, the output terminal of the light-receiving element PD1 is electrically connected to the input terminal of the current-voltage conversion circuit 10 via the connection line 129 and the switching element 104 during the test of the current-voltage conversion circuit 10.

The test voltage applied to the test terminal TP is converted to a test current according to the resistor R10 and the Vbe of the bipolar transistor Q1. At this time, a current equal to the test current is generated at the output terminal of the current-mirror circuit 110A (the current is hereinafter referred to as a mirror current). The mirror current is converted into an output voltage Vout of the light-receiving amplifier circuit 102 through passing through a conversion resistor Rg_a.

At this time, the dummy light-receiving element PD_D in the second test circuit 320 is reverse-biased. Thus, little current flows through the second test circuit 320. However, when the dummy light-receiving element PD_D is large in area, there is an increase in a leak current (a dark current) which may have influence on the first test circuit 310.

In order to solve this problem, the second test circuit 320 according to Variation of Embodiment 2 is provided with the P-channel MOS transistor 321. The P-channel MOS transistor 321 turns off while the test voltage is applied to the test terminal TP. This reduces current leakage from the dummy light-receiving element PD_D, thereby reducing the influence on the first test circuit 310.

The following is a description of test of the connection line 229 using the second test circuit 320. As with Embodiment 2, the test current source which passes a test current from the dummy light-receiving element PD_D to the test terminal TP is connected to the test terminal TP. With this configuration, a predetermined test current is drawn from the test terminal TP.

Furthermore, the dummy light-receiving element PD_D functions as a diode, and then the P-channel MOS transistor 321 turns on. Consequently, the output terminal of the dummy light-receiving element PD_D is electrically connected to the test terminal TP via the connection line 229 and the P-channel MOS transistor 321 during the test of the connection line 229.

Thus, a test terminal voltage is generated at the test terminal TP. The generated test terminal voltage is lower than 0 V. The generated test terminal voltage is a total of a forward voltage across the dummy light-receiving element PD_D, a threshold voltage (Vt) of the P-channel MOS transistor 321, and a drop in voltage due to connection line resistance. The connection line resistance is resistance produced by connection of first-layer aluminum lines 222, the second-layer aluminum line 223, and the contacts 224 to each other.

In the first test circuit 310, as the voltage at the test terminal TP is lower than 0 V, the N-channel MOS transistor 311 turns off. Thus, the first test circuit 310 is out of operation. On the other hand, a parasitic diode which is formed of a PN junction between the drain and a backgate turns on due to the structure of the N-channel MOS transistor 311. Thus, if the resistance of the resistor R10 is low, a current flows from the drain of the N-channel MOS transistor 311 to the test terminal TP via the resistor R10.

In order to prevent this, the resistor R10 has a sufficiently larger resistance than the connection line resistance as with Embodiment 2. For example, the resistance of the resistor R10 is 2 kΩ or higher. This reduces influence of the current from the first test circuit 310; thus allowing accurate test of the connection line resistance.

As described above, the connection line 229 has electrical characteristics identical to those of the connection line 129. Thus, the connection line 129 is tested by testing the connection line 229.

Furthermore, as with Embodiment 1, characteristics of the dummy light-receiving element PD_D (and thus the light-receiving element PD1) are also tested by measuring a test terminal voltage when the test current source is connected to the test terminal TP.

As with Embodiment 2, in the case where the first-layer aluminum lines 222, the second-layer aluminum line 223, and the contacts 224 included in the connection line 229 are normally formed, a normal curve represented by a solid line shown in FIG. 12 is observed.

On the other hand, in the case where the first-layer aluminum lines 222, the second-layer aluminum line 223, and the contacts 224 are connected so that a resistance larger than a predetermined resistance is produced for a reason such as anomalous diffusion, an anomalous curve shown in FIG. 12 is observed.

In the case where an anomalous curve is observed, it is presumed that there is a similar problem with all of the first-layer aluminum lines 105, the second-layer aluminum line 106, and the contacts 107 of the light-receiving amplifier circuit 102 in the same chip as the second test circuit 320. This is how a problem with the connection line 129 is presumed through an alternative test using the connection line 229.

In other words, characteristics of the dummy light-receiving element PD_D (and thus the light-receiving element PD1) and the connection line 129 are tested by measuring the test terminal voltage of the test terminal TP to which the test current source is connected.

It is noted that the bias of the PN junction between the backgate of the N-channel MOS transistor 311 and the drain is zero when the voltage of the backgate is equal to the voltage of the test terminal TP. Thus, the parasitic diode turns off, and no current flows from the first test circuit 310 to the test terminal TP.

On the other hand, in the case where the light-receiving amplifier circuit 102 is in normal operation, that is, where a photocurrent is converted into a voltage and outputted from the light-receiving amplifier circuit 102, the test terminal TP is open. Thus, neither the current-mirror circuit 110A in the first test circuit 310 nor the dummy light-receiving element used in the second test circuit 320 receives the test current.

All the current flowing through the conversion resistor Rg_a connected between the inverting input terminal and the output terminal of the amplifier unit 11 of the light-receiving amplifier circuit 102 is the current from the light-receiving element PD1. As a result, the light-receiving amplifier circuit 102 operates normally with no influence of the test circuit 300.

The test circuit 300 according to Variation of Embodiment 2 allows tests of the current-voltage conversion circuit 10 and a resistance value of the connection line 129 with higher accuracy by using one test terminal TP. The dummy light-receiving element PD_D (and thus the light-receiving element PD1) is also tested when the connection line 129 is tested.

### Embodiment 3

The following is a description of an optical pickup device 550 in which one of the optical semiconductor devices 1000, 1000A and 1000B is used.

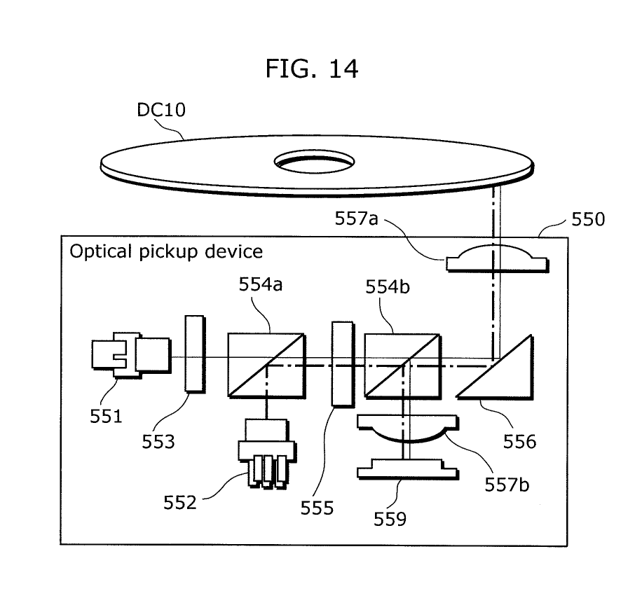

FIG. 14 shows an example of a configuration of the optical pickup device 550. An optical disc DC10 is also shown in FIG. 14 for the purpose of illustration. The optical disc DC10 may be a compact disc (CD), a digital versatile disc (DVD), or a Blu-ray disc (BD).

The optical pickup device 550 reads out information from the optical disc DC10 and writes information to the optical disc DC10 using laser beams.

The optical pickup device 550 includes an infrared laser element 551, a red laser element 552, a three-beam grating 553, a beam splitter 554a, a beam splitter 554b, a collimator lens 555, a mirror 556, object lenses 557a and 557b, and a light-receiving IC 559.

The infrared laser element 551 is a light source which emits a laser beam to be used with CDs. The infrared laser element 552 is a light source which emits a laser beam to be used with DVDs.

Assuming that the optical disc DC10 is a CD, the laser beam emitted from the infrared laser element 551 is split into three beams by the three-beam grating 553, passes the beam splitter 554a, the collimator lens 555, and the beam splitter 554b in order, and is then reflected on the mirror 556 to enter the object lens 557a.

Next, the laser beam is converged by the object lens 557a, enters the optical disc DC10, and is then reflected to be a reflected light. The reflected light returns to the beam splitter 554b via the object lens 557a and the mirror 556 in order.

The reflected light returned from the optical disc DC10 is bent by the beam splitter 554b, and passed on to the light-receiving surface of the light-receiving IC 559 via the object lens 557b. The light-receiving IC 559 outputs information read out from the optical disc DC10 as an electric signal.

The light-receiving IC 559 is an IC formed on a single silicon substrate. The light-receiving IC 559 includes an optical semiconductor device 1000 and an arithmetic circuit which is not shown in FIG. 14. The arithmetic circuit performs arithmetic processing using a signal provided from a light-receiving amplifier circuit A which is included in the light-receiving IC 559. The optical semiconductor device 1000 includes a light-receiving element PD1. Accordingly, the light-receiving element PD1 thus includes the light-receiving IC 559. In the case where light-receiving IC 559 includes the optical semiconductor device 1000, the light-receiving amplifier circuit A in the light-receiving IC 559 is the light-receiving amplifier circuit 101.

The light-receiving IC 559 may be a device in which the optical semiconductor device 1000A or the optical semiconductor device 1000B is used in place of the optical semiconductor device 1000. In other words, the optical pickup device 550 is a device which includes one of the test circuits 100, 200, and 300.

The reflected light from the optical disc DC10 includes information on pits in the optical disc DC10. The light-receiving IC 559 obtains an information signal, a focus error signal, and a tracking error signal of the optical disc DC10 by performing arithmetic processing on the photocurrent generated in the light-receiving element PD1.

These signals are used for reading the optical disc DC10 or controlling the position of the optical pickup device 550 When the optical disc DC10 rotates faster (in high-speed writing or high-speed playback, for example), the transmission rate of the information on pits also increases, for example, to 100 MHz or higher. In this case, the response speed of the light-receiving amplifier circuit A needs to be faster than the transmission rate in order to process the signals.

In this case, if the connection line is formed so that a resistance value of the connection line between the light-receiving element PD1 and the current-voltage conversion circuit 10 is greater than a predetermined value, a response speed of the light-receiving amplifier circuit A goes lower, slowing the transmission of the pit information.

Accordingly, the response speed of the light-receiving amplifier circuit A is ensured by testing the resistance value of the connection line between the light-receiving element PD1 and the current-voltage conversion circuit A using one of the test circuits 100, 200, and 300 As a result, the response speed of the optical pickup device 550 is also ensured.

Assuming that the optical disc DC10 is a DVD, the laser beam emitted from the red laser element 552 passes the beam splitter 554a, the collimator lens 555, and the beam splitter 554b in order, and is then reflected on the mirror 556 to enter the object lens 557a.

Next, the laser beam is gathered by the object lens 557a, enters the optical disc DC10, and is then reflected to be a reflected light. The reflected light returns to the beam splitter 554b via the object lens 557a and the mirror 556 in order.

The reflected light returned from the optical disc DC10 is bent by the beam splitter 554b, and passed on to the light-receiving surface of the light-receiving IC 559 via the object lens 557b. The light-receiving IC 559 outputs information read out from the optical disc DC10 as an electric signal.

As with the case of the CD mentioned above, signals derived from the light reflected from the optical disc DC10 are used for reading the optical disc DC10 or controlling the position of the optical pickup device 550. In the case where the optical disc DC10 is a CD, the laser beam is split into three beams. On the other hand, in the case where the optical disc DC10 is a DVD, the laser beam is not split. Thus, the light reflected from a CD and the light reflected from a DVD is passed to different positions on the light-receiving unit.

Accordingly, in the light-receiving IC 559, a light-receiving unit used to obtain information from a CD is partially different from a light-receiving unit used to obtain information from a DVD.

In the optical pickup device 550, the infrared laser element 551 and the red laser element 552 are adjusted so that laser beams emitted from these laser elements have light paths with similar axes. The light paths extend from the beam splitter 554a to the optical disc DC10, and from the optical disc DC10 to the light-receiving IC 559.

Thus, whether the optical disc DC10 is a CD or a DVD, the same optical elements and light-receiving system can be used. As a result, reduction in size and adjustment during assembly of the optical pickup device 550 are made easier.

As described above, one of the test circuits 100, 200, and 300 is used in the optical pickup device 550 according to Embodiment 3. As a result, the optical pickup device 550 is provided inexpensively.

It is noted that the laser beams, the structure of the light-receiving IC, and arrangement of the components used in the optical pickup device 550 may be adaptively modified depending on design. For example, a light-receiving element, an amplifier unit, and an arithmetic circuit in the optical semiconductor device may be formed in individual IC chips.

Although only some exemplary embodiments of test circuits and an optical pickup device in which one of the test circuits is used according to the present invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is applicable to a test circuit for testing a current-voltage conversion circuit included in a light-receiving amplifier circuit and an optical pickup device in which the test circuit is used. In particular, the present invention is applicable to a test circuit for a light-receiving amplifier circuit which reads out information recorder on optical discs and a device, such as an optical pickup device, in which the test circuit is used.

What is claimed is:

1. A test circuit for testing characteristics of a current-voltage conversion circuit which outputs a voltage corresponding to a photocurrent generated by a light-receiving element corresponding to an amount of light with which the light-receiving element is irradiated,
said test circuit comprising:
a current-mirror circuit which includes a first bipolar transistor and a second bipolar transistor which is electrically connected to the light-receiving element;
a dummy light-receiving element which is identical to the light-receiving element and equivalent in characteristics to the light-receiving element; and
a test terminal which is electrically connected to said first bipolar transistor and said dummy light-receiving element.

2. The test circuit according to claim 1,
wherein, when a voltage for testing the current-voltage conversion circuit is applied to said test terminal, said current-mirror circuit causes, by using said second bipolar transistor, a test current for testing the characteristics of the current-voltage conversion circuit to be generated in the current-voltage conversion circuit, and
said first bipolar transistor in said current-mirror circuit turns off when the test current for testing the characteristics of said dummy light-receiving element flows from said dummy light-receiving element to said test terminal.

3. The test circuit according to claim 1,
wherein said first bipolar transistor is an NPN transistor,
the NPN transistor is formed in a P-type substrate, and
said dummy light-receiving element is formed of the P-type substrate and an N-type diffusion region which is a collector region of the NPN transistor.

4. The test circuit according to claim 1,
wherein a first light-receiving region of said dummy light-receiving element for receiving light in the first light-receiving region has an area equal to or larger than an area of a second light-receiving region of the light-receiving region for receiving light in the second light-receiving region.

5. The test circuit according to claim 4,
wherein the first light-receiving region of the dummy light-receiving element is covered with a photo-shield film so as not to be irradiated with light.

6. An optical pickup device comprising
the test circuit according to claim 1.

7. A test circuit for testing a current-voltage conversion circuit included in a light-receiving amplifier circuit formed on a substrate,
the light-receiving amplifier circuit including:
a light-receiving element which generates a photocurrent corresponding to an amount of light with which the light-receiving element is irradiated;
a current-voltage conversion circuit which converts the photocurrent to a voltage; and
a first connection line which includes lines provided in wiring layers on the substrate and contacts,
wherein the light-receiving element has an output terminal which is electrically connected to an input terminal of the current-voltage conversion circuit via at least the first connection line during test of the current-voltage conversion circuit,
said test circuit comprising:
a test terminal;
a first test circuit; and
a second test circuit,
wherein said first test circuit includes:
a current-mirror circuit having an input terminal and an output terminal; and
a resistor,
said input terminal of said current-mirror circuit is electrically connected to said test terminal via at least said resistor, and
said output terminal of said current-mirror circuit is electrically connected to the output terminal of the light-receiving element,
said second test circuit includes:
a dummy light-receiving element which is an element identical to the light-receiving element and equivalent in characteristics to the light-receiving element; and
a second connection line which is identical in structure to the first connection line and equivalent in characteristics to the first connection line, and
said dummy light-receiving element has an output terminal which is electrically connected to said test terminal via at least said second connection line during test of said second connection line.

8. The test circuit according to claim 7,
wherein, when a voltage for testing the current-voltage conversion circuit is applied to said test terminal during the test of the current-voltage conversion circuit, said current-mirror circuit causes a test current for testing characteristics of the current-voltage conversion circuit to be generated in the current-voltage conversion circuit.

9. The test circuit according to claim 7,
wherein said first test circuit is out of operation while a test current for testing said second connection line and said dummy light-receiving element flows from said dummy light-receiving element to said test terminal.

10. The test circuit according to claim 7,
wherein a resistance of said resistor is 2 kΩ or higher.

11. The test circuit according to claim 7,
wherein said first test circuit further includes an N-channel MOS transistor,
said N-channel MOS transistor is provided between said resistor and said input terminal of said current-mirror circuit,
said N-channel MOS transistor has a source which is connected to said input terminal of said current-mirror circuit, and
said N-channel MOS transistor has a gate and a drain which are connected to one end of said resistor.

12. The test circuit according to claim 7,
wherein said second test circuit further includes a P-channel MOS transistor,
said P-channel MOS transistor is provided between said second connection line and said test terminal,
said P-channel MOS transistor has a source which is connected to said second connection line, and
said P-channel MOS transistor has a gate and a drain which are connected to said test terminal.

13. The test circuit according to claim 7,
wherein the light-receiving amplifier circuit further includes a switching element which electrically connects and disconnects the output terminal of the light-receiving element and the input terminal of the current-voltage conversion circuit, and
the switching element is connected in series to the first connection line.

14. The test circuit according to claim 7,
wherein said dummy light-receiving element is covered with a photo-shield film.

15. The test circuit according to claim 14,
wherein said photo-shield film is a metal film provided in an uppermost layer of the wiring layers.

16. An optical pickup device comprising
said test circuit according to claim 7.
